(19) United States
(12) Patent Application Publication
(10) Pub. No.: US 2025/0185523 A1
(43) Pub. Date: Jun. 5, 2025

(54) LOW VOLTAGE RESISTIVE RANDOM ACCESS MEMORY (RRAM) CELLS AND METHOD OF FORMATION

(71) Applicant: Silicon Storage Technology, Inc., San Jose, CA (US)

(72) Inventors: FENG ZHOU, Fremont, CA (US); XIAN LIU, Sunnyvale, CA (US); STEVEN LEMKE, Boulder Creek, CA (US); YURI TKACHEV, Sunnyvale, CA (US); HIEU VAN TRAN, San jose, CA (US); NHAN DO, Saratoga, CA (US)

(21) Appl. No.: 18/438,371

(22) Filed: Feb. 9, 2024

Related U.S. Application Data
(60) Provisional application No. 63/606,025, filed on Dec. 4, 2023.

(51) Int. Cl. H10N 70/00; H10B 63/00; H10N 70/20

(52) U.S. Cl. CPC H10N 70/041; H10B 63/30; H10N 70/063; H10N 70/24; H10N 70/8833

(57) ABSTRACT

A memory device, and method of formation, that includes a first insulation material disposed over a semiconductor substrate. A first conductive contact extends through the first insulation material. A second block of conductive material is disposed on the first insulation material and on, and in electrical contact with, the first conductive contact. A block of resistive switching dielectric material is disposed directly on the second block of conductive material. A first block of conductive material is disposed directly on the block of resistive switching dielectric material. The block of resistive switching dielectric material and the first block of conductive material are displaced laterally from the first conductive contact. An insulation layer is disposed over the first block of conductive material, the block of resistive switching dielectric material and the second block of conductive material.

### RELATED APPLICATIONS

This application claims the benefit of U.S. Provisional Application No. 63/606,025, filed Dec. 4, 2023, and which is incorporated herein by reference.

### FIELD OF THE INVENTION

The present invention relates to non-volatile memory, and more specifically to resistive random access memory.

### BACKGROUND OF THE INVENTION

Resistive random access memory (RRAM) is a type of nonvolatile memory. Generally, RRAM memory cells each include a resistive switching dielectric material layer sandwiched between two conductive electrodes. The resistive switching dielectric material is normally insulating. However, by applying the proper voltage across the resistive switching dielectric material layer, a conduction path (typically referred to as a filament) can be formed through the resistive switching dielectric material layer resulting in a lower resistance across the RRAM cell. Once the filament is formed, it can be “reset” (i.e., broken or ruptured, resulting in a high resistance across the RRAM cell) and set (i.e., re-formed, again resulting in a lower resistance across the RRAM cell), by applying the appropriate voltages across the resistive switching dielectric material layer. The low and high resistance states can be utilized to indicate a digital state of “1” or “0” depending upon the resistance state, and thereby provide a reprogrammable non-volatile memory cell that can store a bit of information.

FIG. 1 shows a conventional configuration of an RRAM memory cell 1. The memory cell 1 includes a resistive switching dielectric material layer 2 sandwiched between two conductive material layers that form upper and lower electrodes 3 and 4, respectively.

FIGS. 2A-2D show the switching mechanism of the resistive switching dielectric material layer 2. Specifically, FIG. 2A shows the resistive switching dielectric material layer 2 in its initial state after fabrication, where the layer 2 exhibits a relatively high resistance. FIG. 2B shows the formation of a conductive filament 7 through the layer 2 by applying the appropriate voltage across the layer 2. The filament 7 is a conductive path through the layer 2, such that the layer exhibits a relatively low resistance across it (because of the relatively high conductivity of the filament 7). FIG. 2C shows the formation of a rupture 8 in filament 7 caused by the application of a “reset” voltage across the layer 2. The area of the rupture 8 has a relatively high resistance, so that layer 2 exhibits a relatively high resistance across it. FIG. 2D shows the restoration of the filament 7 in the area of the rupture 8 caused by the application of a “set” voltage across layer 2. The restored filament 7 means the layer 2 exhibits a relatively low resistance across it. The relatively low resistance of layer 2 in the “formed” or “set” states of FIGS. 2B and 2D respectively can represent a digital state (e.g. a “1”), and the relatively high resistance of layer 2 in the “reset” state of FIG. 2C can represent a different digital state (e.g. a “0”). The reset voltage (which breaks the filament) can have a polarity opposite that of the filament formation and the set voltages, but it can also have the same polarity. The RRAM cell 1 can repeatedly be “reset” and “set,” so it forms a reprogrammable nonvolatile memory cell.

The filament formation voltage for RRAM cells can be undesirably high, such that standard input/output transistors operating at, for example, 1.8 V, 2.5 V or even 3.3V may not be able to reliably form the filament. In addition, large cell to cell variations can be caused by resistive switching dielectric material layer thickness variations and resistive switching dielectric material surface roughness variations, along with other process non-uniformities, thus lowering its endurance performance. There is a need for an improved methodology for fabricating RRAM cells.

### BRIEF SUMMARY OF THE INVENTION

The aforementioned problems and needs are addressed by a method of forming a memory device that includes forming first insulation material over a semiconductor substrate; forming a first contact hole extending through the first insulation material; forming a first conductive contact in the first contact hole; forming a first layer of conductive material on the first insulation material and on, and in electrical contact with, the first conductive contact; forming a layer of resistive switching dielectric material directly on the first layer of conductive material; performing a first anneal process on the layer of resistive switching dielectric material; forming a second layer of conductive material directly on the layer of resistive switching dielectric material; performing a second anneal process on the second layer of conductive material; selectively removing portions of the second layer of conductive material to form a first block of conductive material; selectively removing portions of the layer of resistive switching dielectric material to form a block of resistive switching dielectric material; selectively removing portions of the first layer of conductive material to form a second block of conductive material, wherein the first block of conductive material is disposed directly on the block of resistive switching dielectric material, and the block of resistive switching dielectric material is disposed directly on the second block of conductive material, and wherein the first block of conductive material and the block of resistive switching dielectric material are displaced laterally from the first conductive contact; and forming an insulation layer over the first block of conductive material, the block of resistive switching dielectric material and the second block of conductive material.

A method of forming a memory device includes forming first insulation material over a semiconductor substrate; forming a first contact hole extending through the first insulation material; forming a first conductive contact in the first contact hole; forming a first layer of conductive material on the first insulation material and on, and in electrical contact with, the first conductive contact; forming a layer of resistive switching dielectric material directly on the first layer of conductive material; performing a first anneal process on the layer of resistive switching dielectric material; forming a second layer of conductive material directly on the layer of resistive switching dielectric material; selectively removing portions of the second layer of conductive material to form a first block of conductive material; selectively removing portions of the layer of resistive switching dielectric material to form a block of resistive switching dielectric material; selectively removing portions of the first layer of conductive material to form a second block of conductive material, wherein the first block of conductive material is disposed directly on the block of resistive switching dielectric material, and the block of resistive switching dielectric material is disposed directly on the second block of conductive material, and wherein the first block of conductive material and the block of resistive switching dielectric material are displaced laterally from the first conductive contact; forming an insulation layer over the first block of conductive material, the block of resistive switching dielectric material and the second block of conductive material; and performing a third anneal process on the insulation layer.

A memory device includes a first insulation material disposed over a semiconductor substrate; a first conductive contact extending through the first insulation material; a second block of conductive material disposed on the first insulation material and on, and in electrical contact with, the first conductive contact; a block of resistive switching dielectric material disposed directly on the second block of conductive material; a first block of conductive material disposed directly on the block of resistive switching dielectric material, wherein the block of resistive switching dielectric material and the first block of conductive material are displaced laterally from the first conductive contact; and an insulation layer over the first block of conductive material, the block of resistive switching dielectric material and the second block of conductive material.

Other objects and features of the present disclosure will become apparent by a review of the specification, claims and appended figures.

### BRIEF DESCRIPTION OF THE DRAWINGS

FIG. 1 is a side cross sectional view of a conventional RRAM memory cell.

FIG. 2A is a side cross sectional view of a conventional RRAM memory cell in its initial state.

FIG. 2B is a side cross sectional view of a conventional RRAM memory cell illustrating the formation of a conductive filament.

FIG. 2C is a side cross sectional view of a conventional RRAM memory cell illustrating the formation of a rupture in the conductive filament.

FIG. 2D is a side cross sectional view of a conventional RRAM memory cell illustrating the restoration of the conductive filament in the area of the rupture.

FIGS. 3A-3H are side cross sectional views illustrating the formation of a RRAM memory cell.

FIG. 4 is a graph showing the filament forming voltages (in arbitrary units AU) as a function of current (in arbitrary units AU) for RRAM memory cells formed without anneal processes and RRAM memory cells formed with anneal processes.

FIG. 5 is a graph showing the filament set/reset voltages (in arbitrary units AU) as a function of current (in arbitrary units (AU) for RRAM memory cells formed without anneal processes and RRAM memory cells formed with anneal processes.

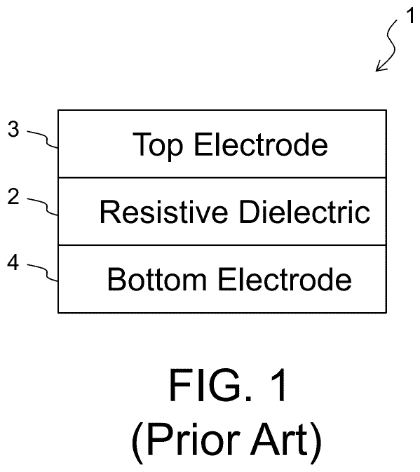

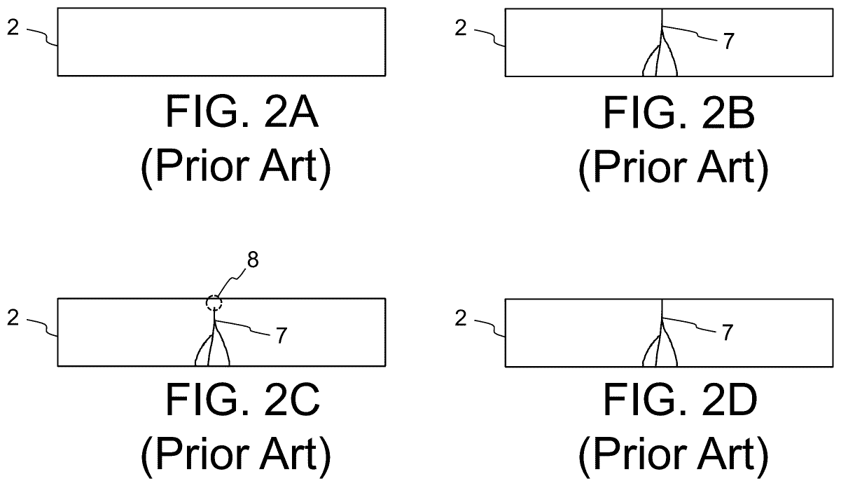

### DETAILED DESCRIPTION OF THE INVENTION

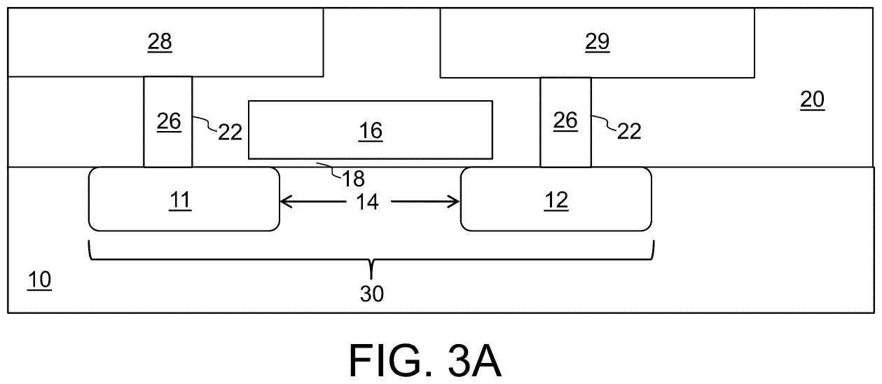

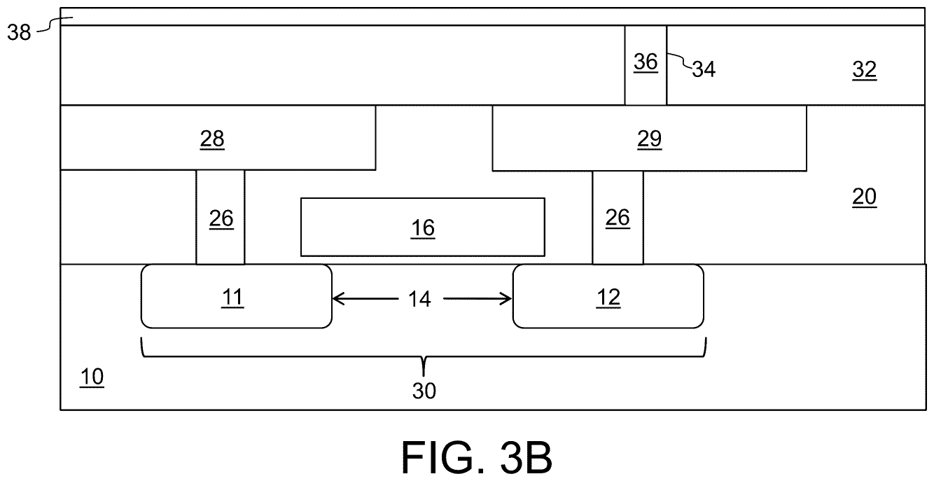

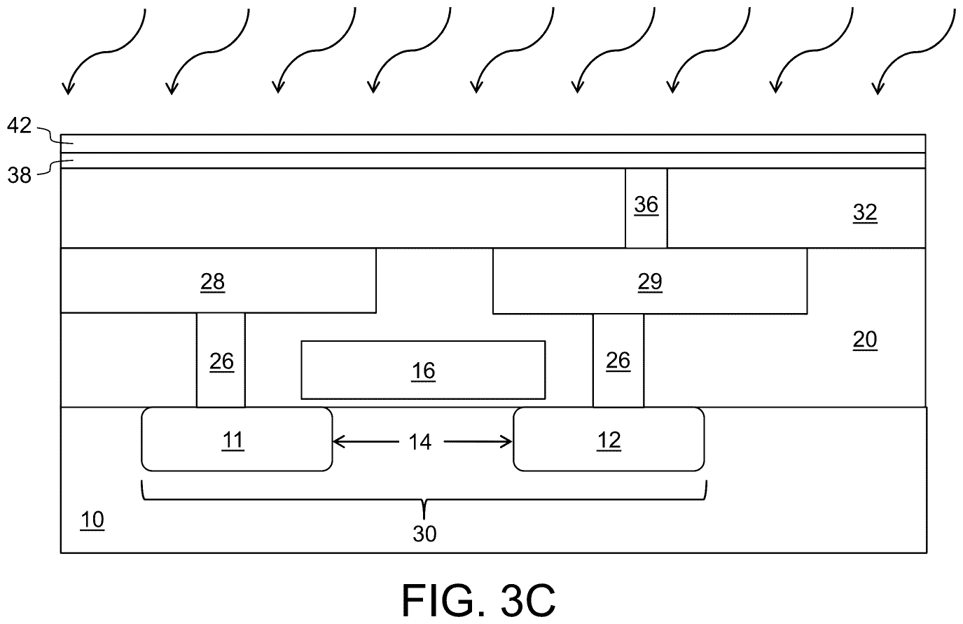

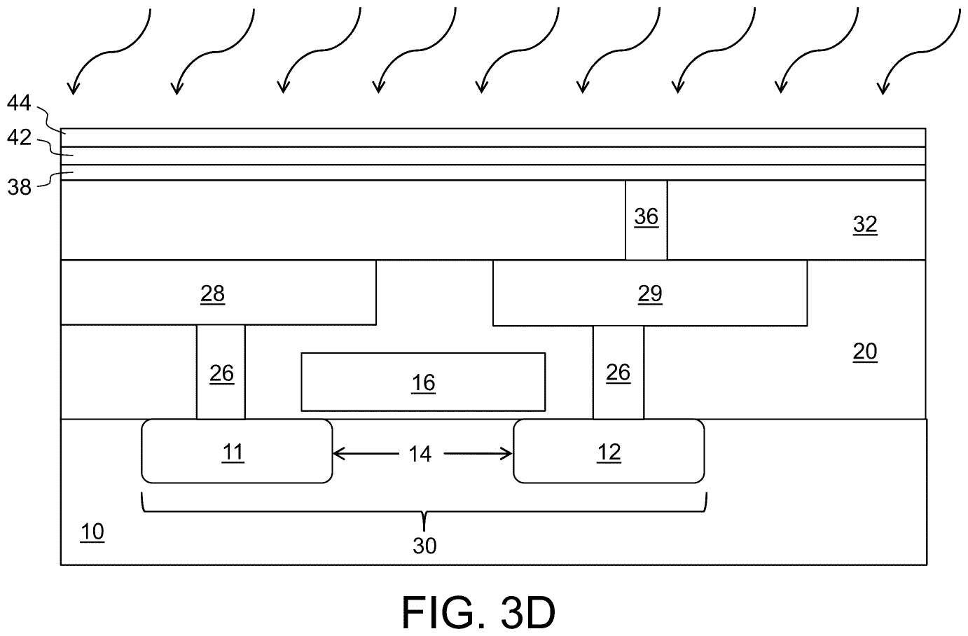

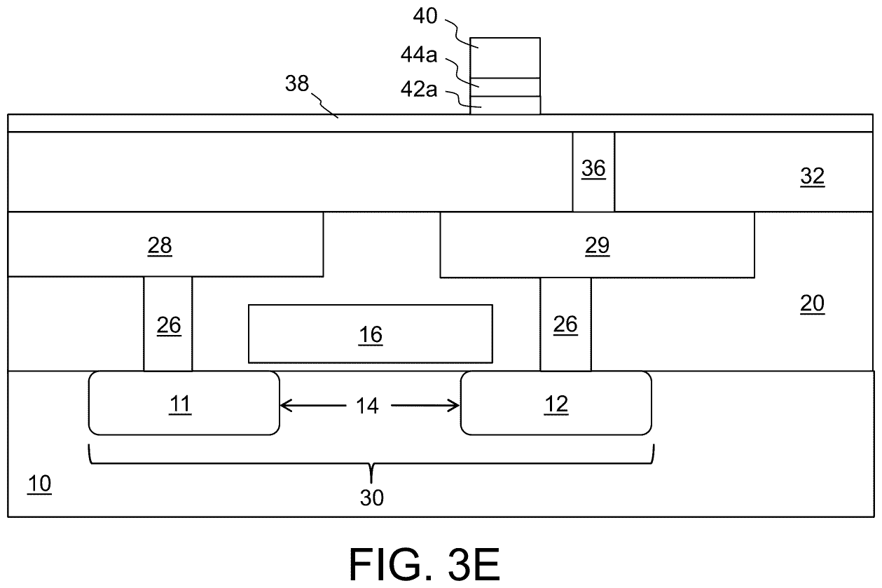

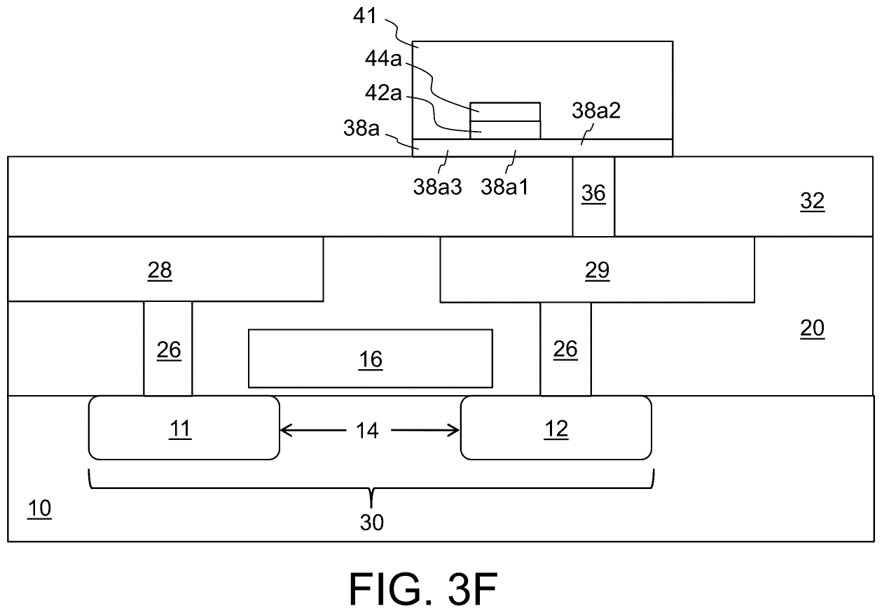

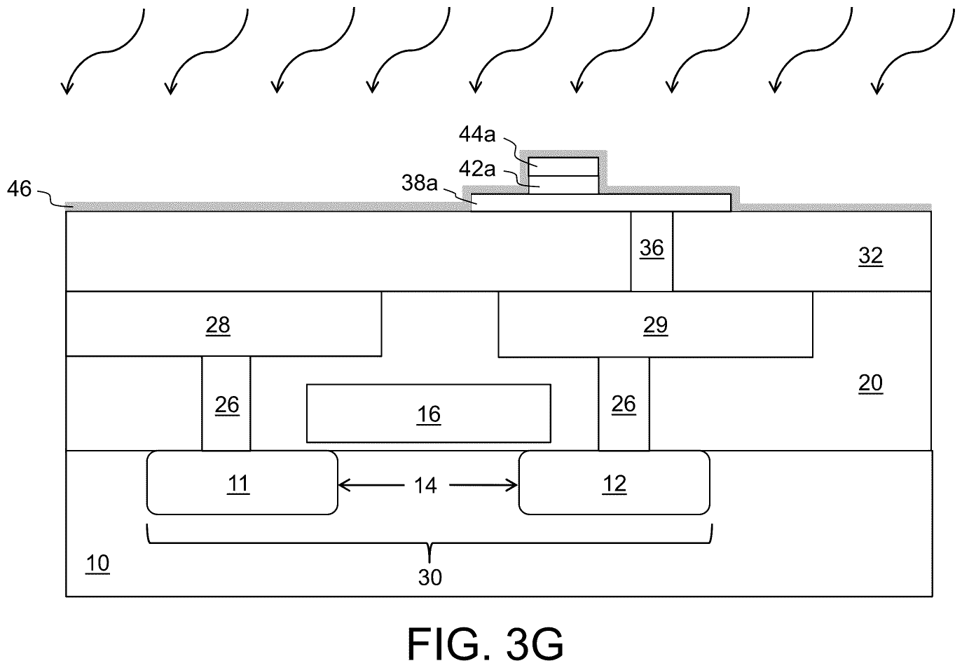

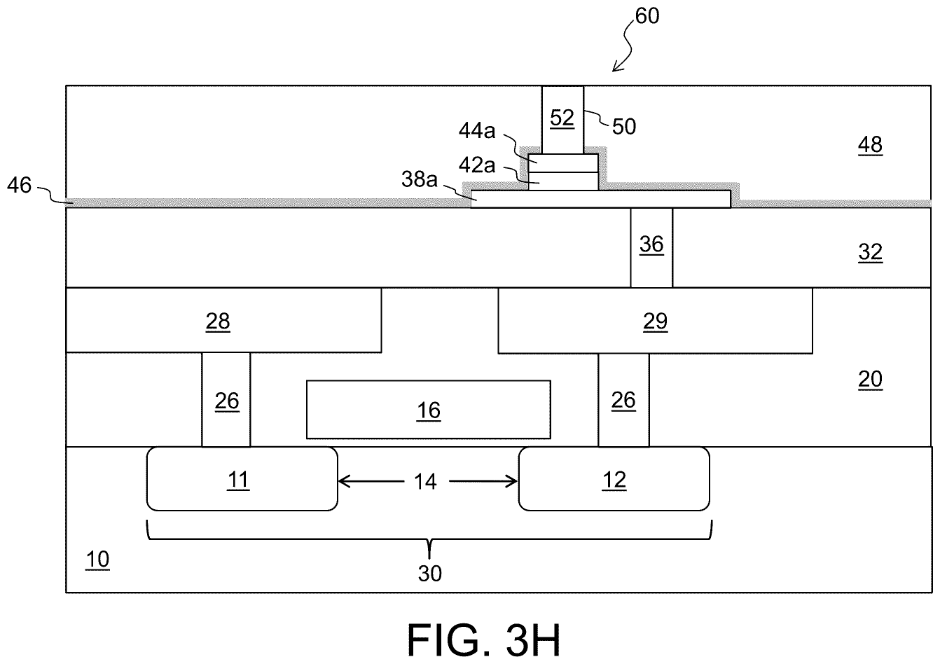

A fabrication method is disclosed that can improve the resistive switching dielectric material quality, thus reducing the forming voltages, and reducing cell to cell variations. The method of forming a memory device with RRAM cells is shown in FIGS. 3A-3H, and starts by forming the structure shown in FIG. 3A. Specifically, a source region 11 and drain region 12 having a first conductivity type (e.g., n+) are formed in a semiconductor substrate 10 (e.g. silicon) having a second conductivity type (e.g., p+), by for example implantation, which define a channel region 14 in the semiconductor substrate 10 extending between the source and drain regions 11/12. A conductive gate 16 (e.g., made of conductive material such as polysilicon or metal) is formed over and insulated from channel region 14 of the semiconductor substrate 10. Conductive gate formation can include formation of an oxide layer 18 (e.g., silicon oxide, silicon dioxide, hafnium oxide, and combinations thereof) which is an insulation material between the semiconductor substrate 10 and the conductive gate 16, followed by a polysilicon deposition on the oxide layer 18, followed by a photolithography and etch process (e.g. photo resist deposition, exposure and selective removal, followed by poly etch) that selectively removes the polysilicon layer except for that portion thereof that constitutes conductive gate 16. Insulation material 20 (e.g. another oxide layer) is then formed over the semiconductor substrate 10. Contact holes 22 are formed in insulation material 20 by a photolithography and an etch process. Contact metal is then deposited, followed by a chemical mechanical polish (CMP) to fill contact holes 22 with metal material to form contacts 26 that electrically connect to the exposed source and drain regions 11/12. A layer of metal is deposited on the structure, followed by a CMP process. The metal layer is then patterned using a photolithography and metal etch process, leaving a conductive source line contact 28 in electrical contact with one of the contacts 26 which in turn is in electrical contact with the source region 11, and a drain contact 29 in electrical contact with the other one of the contacts 26 which is in turn in electrical contact with the drain region 12. Additional insulation is deposited to raise insulation material 20 even with the tops of contacts 28 and 29 (e.g., by oxide deposition and etch). Contacts 26 thus electrically connect the source and drain regions 11/12 to the source and drain contacts 28/29 respectively. The source and drain regions 11/12, channel region 14 and the conductive gate 16 form a select transistor 30 for selectively operating the RRAM cell being formed next. The resulting structure is shown in FIG. 3A.

Insulation material 32 (e.g. oxide) (also referred to herein as first insulation material) is formed over the semiconductor substrate 10, and specifically over upper surfaces of insulation material 20 and source and drain contacts 28/29. A photolithographic and etch process is then used to form a contact hole 34 that extends through first insulation material 32 to expose contact 29. The contact hole 34 is filled with conductive material to form conductive contact 36 (also referred to herein as first conductive contact) that extends through the first insulation material 32. While the figures only show a single first conductive contact 36, there is a first conductive contact 36 extending up from one of the contacts 29 for respective ones of the RRAM memory cells being formed on semiconductor substrate 10. A conductive layer 38 is formed on the upper surfaces of first insulation material 32 and first conductive contact 36. Conductive layer 38 can be made of TiN, TaN, HfN, TaAlN, Ti, Ta, Pt, Iridium, or Ruthenium. The resulting structure is shown in FIG. 3B. Conductive layer 38 will eventually constitute the lower electrode of the RRAM cell.

A layer of resistive switching dielectric material 42 is then formed directly on the conductive layer 38, as shown in FIG. 3C. Resistive switching dielectric material layer 42 can be a single layer of switching oxide such as a transition metal oxide (e.g., HfO₂, Al₂O₃, TaOₓ, TiOₓ, WOₓ, VOₓ, CuOₓ). The resistive switching dielectric material layer 42 can also include multiple sublayers of different oxides and metals. Non-limiting examples of sublayers that can be included in dielectric material layer 42 can include a sublayer of oxygen scavenger metal such as Ti or Ta on a sublayer of a transition metal oxide (e.g., HfO₂, Al₂O₃, TaOₓ, TiOₓ, WOₓ, VOₓ, CuOₓ), or a sublayer of HfO₂ and a sublayer of Al₂O₃, or a sublayer of HfO₂ and a sublayer of Hf and a sublayer of TaOₓ, or a sublayer of HfO₂ and a sublayer of Ti and a sublayer of TiOₓ. Resistive switching dielectric material layer 42 is then annealed in a first anneal process (e.g., Rapid Thermal Anneal (RTA), Flash Lamp Anneal (Flash), Laser Spike Anneal (LSA), at a temperature of 200-600° C. for 10-1000 seconds in an N₂ atmosphere), as shown in FIG. 3C. A second conductive layer 44 is formed directly on resistive switching dielectric material layer 42 and then annealed in a second anneal process, as shown in FIG. 3D. Second conductive layer 44 can be TiN, TaN, HfN, TaAlN, Ti, Ta, Pt, Iridium, or Ruthenium, the formation of which is followed by the second anneal process (e.g., RTA, Flash, LSA, at a temperature of 200-600° C. for 10-1000 seconds in an N₂ atmosphere). There is no requirement that the first and second anneal processes be identical in terms of temperature, annealing process or profile.

A photolithography and etch process (also referred to herein as first photolithography and etch process) is performed that can include photo resist deposition, exposure and selective removal leaving a first block of photo resist 40 on second conductive layer 44, followed by one or more etches, to selectively remove portions of layers 44 and 42 except for portions under the first block of photo resist 40, leaving a first block of conductive material 44a (remains of second conductive layer 44) which will serve as the upper electrode, and a block of resistive switching dielectric material 42a (remains of layer 42). The first block of conductive material 44a is disposed on the block of resistive switching dielectric material 42a, both of which can have the same lateral dimension and both are displaced laterally from first conductive contact 36 (i.e., there is no vertical overlap between blocks 44a and 42a on the one hand and first conductive contact 36 on the other hand), as shown in FIG. 3E.

After removal of the first block of photo resist 40, a second photolithography and etch process is performed that can include photo resist deposition, exposure and selective removal leaving a second block of photo resist 41 on first conductive layer 38 and encapsulating the first block of conductive material 44a and the block of resistive switching dielectric material 42a. One or more etches are used to selectively remove portions of layer 38 except for the portion under the second block of photo resist 41, leaving second block of conductive material 38a (remains of the first conductive layer 38) which will serve as the lower electrode. The second block of conductive material 38a includes a first portion 38al under the block of resistive switching dielectric material 42a, a second portion that extends laterally out from underneath the block of resistive switching dielectric material 42a and over first conductive contact 36 (i.e. electrically connecting the block of resistive switching dielectric material 42a to the first conductive contact 36), and a third portion that extends laterally out from underneath the block of resistive switching dielectric material 42 away from first conductive contact 36, as shown in FIG. 3F.

After the second block of photo resist 41 is removed, an insulation layer (e.g. silicon nitride) 46 is deposited over, and encapsulates, the structure, i.e. the insulation layer 46 is deposited over first insulation layer 32, covering first block of conductive material 44a, block of resistive dielectric material 42a and second block of conductive material 38a. The insulation layer 46 is then annealed in a third anneal process (e.g., RTA, Flash, LSA, at a temperature of 200-600° C. for 10-1000 seconds in an N₂ atmosphere), as shown in FIG. 3G. There is no requirement that the first, second and third anneal processes be identical in terms of temperature, annealing process or profile. Insulation material 48 (e.g. oxide) (also referred to herein as second insulation material) is formed on the annealed insulation layer 46. A contact hole 50 is formed through the second insulation material 48 and insulation layer 46 (exposing the first block of conductive material 44a, i.e. upper electrode 44a) by a photolithography and etch process. The contact hole 50 is then filled with a conductive material (e.g., by metal deposition and chemical mechanical polish—CMP) to form a second conductive contact 52 that extends through second insulation material 48 and insulation layer 46. The final structure of the memory device is shown in FIG. 3H.

The RRAM cell 60 includes the upper electrode 44a (first block of conductive material) disposed directly on the block of resistive switching dielectric material 42a, which is disposed directly on the lower electrode 38a (second block of conductive material). Electrical connections to second conductive contact 52, contact 28, and the conductive gate 16 can be implemented through different metal layer connections (not shown). In operation, voltages and currents are applied to the memory cell by contacts 28 and 52 and conductive gate 16. Voltages and current from contact 28 pass through contact 26, through the select transistor 30 (source region 11, channel region 14 under gate 16, drain region 12) when the select transistor 30 is active, through the other contact 26, through contacts 29 and 36, through lower electrode 38a, through the block of resistive switching dielectric material 42a, when the RRAM cell is in the formed or set state, through upper electrode 44a, and through contact 52.

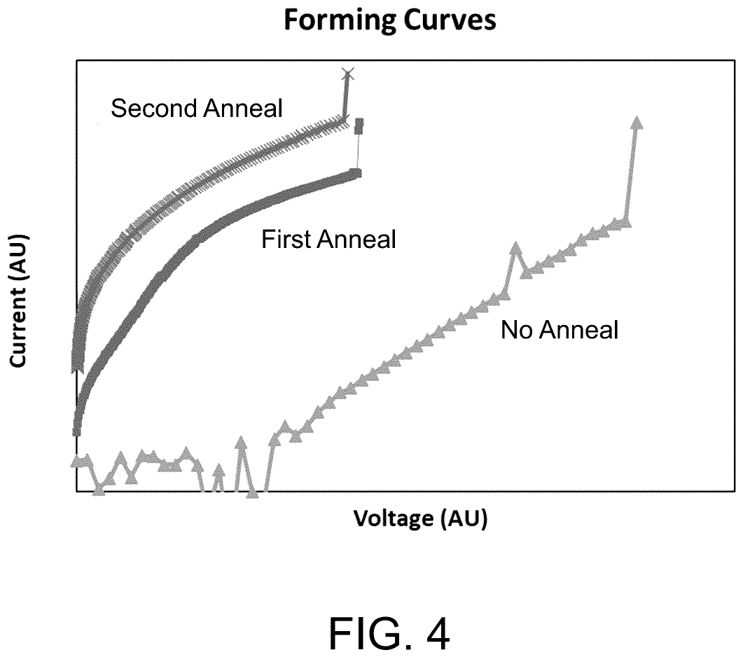

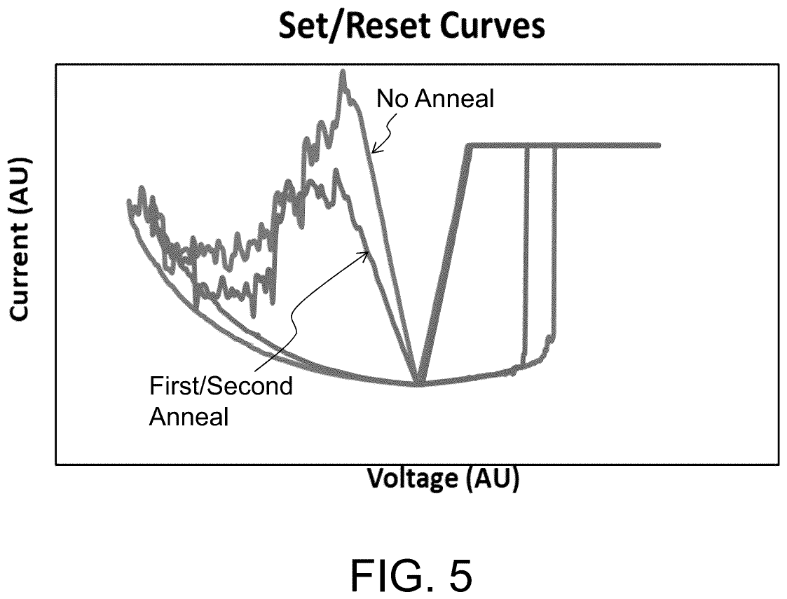

It has been discovered that performing both the first anneal process (after formation of the resistive switching dielectric material layer 42) and the second anneal process (after formation of the second conductive layer 44) can significantly reduce the forming voltage necessary to initially form the filament through the resistive switching dielectric material layer 42a, by as much as 40-50% over performing no anneal process, and even relative to just performing the first anneal process. For example, as shown in FIG. 4, by performing the first and second anneal processes, the forming voltage is significantly reduced. The set/reset voltages can also be reduced by 30-40% by performing the first and second anneal processes, as shown in FIG. 5. These benefits offer the flexibility to use a smaller sized select transistor and reduce the electrical stress during filament forming and switching operations.

It has also been discovered that performing the third anneal process (after the first the first and second anneal processes) can further reduce the forming voltage necessary to initially form the filament through the resistive switching dielectric material layer 42a, and the set/reset voltage, relative to just performing the first and second anneal processes. Therefore, the third anneal process is beneficial when combined with the first and second anneal processes, but is optional.

It has further been discovered that performing the first and third anneal processes, but not the second anneal process, still provides reductions in the forming, set and reset voltages relative to performing just the first anneal process or no anneal process at all. Therefore, in an alternate example, the method of forming the RRAM cell 60 above can be implemented by performing the first and third anneal processes, but omitting the second anneal process.

The above described technique can improve the resistive switching dielectric material quality and also reduce cell-to-cell variations. For example, it has been discovered by the present inventors that surface roughness on the top of first conductive contact 36 could be transferred to block of resistive switching dielectric material 42a if the block of resistive switching dielectric material 42a were formed over (i.e., vertically over and laterally overlapping) the first conductive contact 36, resulting in undesirable surface roughness and non-uniformity that in turn can introduce unwanted cell-to-cell variations. To avoid this problem, the block of resistive switching dielectric material 42a and upper electrode 44a are formed on a portion of lower electrode 38a that is not over first conductive contact 36 (i.e., the block of resistive switching dielectric material 42a and upper electrode 44a are displaced laterally from (i.e., there is no vertical overlap with) the first conductive contact 36) so that any surface roughness of first conductive contact 36 would not be transferred to the block of resistive switching dielectric material 42a.

The above described technique can also reduce metal redeposition that could cause unwanted electrical shorts. Specifically, it has been discovered by the present inventors that if the same photolithograph and etch process is used to define the block of resistive switching dielectric material 42a and the lower electrode 38a, that metal material from the first conductive layer 38 can be redeposited on the sides of the block of resistive switching dielectric material 42a during the etch of first conductive layer 38, which can cause an unwanted electrical short between the upper and lower electrodes 44a, 38a, resulting in a failed device. However, in the above described technique, a first photolithography and etch process is used to define the upper electrode 44a and the block of resistive switching dielectric material 42a (i.e., both have the same lateral dimensions), and a second (different) photolithography and etch process is used to define the lower electrode 38a, where the lower electrode 38a has larger lateral dimensions than the upper electrode 44a and the block of resistive switching dielectric material 42a, to laterally displace the etching of the first conductive layer 38 away from the sidewalls of the block of resistive switching dielectric material 42a, and allow the photo resist 41 for the second photolithography and etch process to protect the sidewalls of the block of resistive switching dielectric material 42a, to prevent redeposited metal material from reaching the sidewalls of the block of resistive switching dielectric material 42a.

Finally, the above technique involves two photolithography and etch processes to define the block of resistive switching dielectric material 42a and its upper and lower electrodes (one defining the upper electrode 44a and the block of resistive switching dielectric material 42a, and one defining the lower electrode 38a), so that their lateral dimensions can be separately defined that can improve the cell yield and reliability.

It is to be understood that the present disclosure is not limited to the example(s) described above and illustrated herein, but encompasses any and all variations falling within the scope of any claims. For example, references to the present disclosure or invention or examples herein are not intended to limit the scope of any claim or claim term, but instead merely make reference to one or more features that may be covered by one or more claims. Materials, processes and numerical examples described above are exemplary only, and should not be deemed to limit the claims. Further, as is apparent from the claims and specification, not all method operations need be performed in the exact order illustrated or claimed, but rather in any order (unless there is an explicitly recited limitation on any order) that allows the proper formation of the memory cells described herein. Single layers of material could be formed as multiple layers of such or similar materials, and vice versa. Lastly, the terms “forming” and “formed” as used herein shall include material deposition, material growth, or any other technique in providing the material as disclosed or claimed.

It should be noted that, as used herein, the terms “over” and “on” both inclusively include “directly on” (no intermediate materials, elements or space disposed there between) and “indirectly on” (intermediate materials, elements or space disposed there between). Likewise, the term “adjacent” includes “directly adjacent” (no intermediate materials, elements or space disposed there between) and “indirectly adjacent” (intermediate materials, elements or space disposed there between), “mounted to” includes “directly mounted to” (no intermediate materials, elements or space disposed there between) and “indirectly mounted to” (intermediate materials, elements or spaced disposed there between), and “electrically coupled” includes “directly electrically coupled to” (no intermediate materials or elements there between that electrically connect the elements together) and “indirectly electrically coupled to” (intermediate materials or elements there between that electrically connect the elements together). For example, forming an element “over a semiconductor substrate” can include forming the element directly on the semiconductor substrate with no intermediate materials/elements there between, as well as forming the element indirectly on the semiconductor substrate with one or more intermediate materials/elements there between.

What is claimed is:

1. A method of forming a memory device, comprising:
forming first insulation material over a semiconductor substrate;
forming a first contact hole extending through the first insulation material;
forming a first conductive contact in the first contact hole;
forming a first layer of conductive material on the first insulation material and on, and in electrical contact with, the first conductive contact;
forming a layer of resistive switching dielectric material directly on the first layer of conductive material;
performing a first anneal process on the layer of resistive switching dielectric material;
forming a second layer of conductive material directly on the layer of resistive switching dielectric material;
performing a second anneal process on the second layer of conductive material;
selectively removing portions of the second layer of conductive material to form a first block of conductive material;
selectively removing portions of the layer of resistive switching dielectric material to form a block of resistive switching dielectric material;
selectively removing portions of the first layer of conductive material to form a second block of conductive material, wherein the first block of conductive material is disposed directly on the block of resistive switching dielectric material, and the block of resistive switching dielectric material is disposed directly on the second block of conductive material, and wherein the first block of conductive material and the block of resistive switching dielectric material are displaced laterally from the first conductive contact; and
forming an insulation layer over the first block of conductive material, the block of resistive switching dielectric material and the second block of conductive material.

2. The method of claim 1, comprising:
performing a third anneal process on the insulation layer.

3. The method of claim 2, wherein the insulation layer is silicon nitride.

4. The method of claim 1, comprising:
forming a second insulation material over the insulation layer;
forming a second contact hole extending through the second insulation material and the insulation layer; and
forming a second conductive contact in the second contact hole;
wherein the second conductive contact is in electrical contact with the first block of conductive material.

5. The method of claim 1, comprising:
forming a first region and a second region of a first conductivity type in the semiconductor substrate, wherein the semiconductor substrate is of a second conductivity type different than the first conductivity type;
forming a conductive gate disposed over and insulated from the semiconductor substrate, and between the first and second regions; and
electrically coupling the first conductive contact to the second region.

6. The method of claim 1, wherein the resistive switching dielectric material includes one of HfO2, Al2O3, TaOx, TiOx, WOx, VOx or CuOx.

7. The method of claim 1, wherein the resistive switching dielectric material includes a sublayer of HfO₂ and a sublayer of Al₂O₃.

8. The method of claim 1, wherein the resistive switching dielectric material includes a sublayer of HfO₂, a sublayer of Hf, and a sublayer of TaOx.

9. The method of claim 1, wherein the resistive switching dielectric material includes a sublayer of HfO₂, a sublayer of Ti, and a sublayer of TiOx.

10. A method of forming a memory device, comprising:
forming first insulation material over a semiconductor substrate;
forming a first contact hole extending through the first insulation material;
forming a first conductive contact in the first contact hole;
forming a first layer of conductive material on the first insulation material and on, and in electrical contact with, the first conductive contact;
forming a layer of resistive switching dielectric material directly on the first layer of conductive material;
performing a first anneal process on the layer of resistive switching dielectric material;
forming a second layer of conductive material directly on the layer of resistive switching dielectric material;
selectively removing portions of the second layer of conductive material to form a first block of conductive material;
selectively removing portions of the layer of resistive switching dielectric material to form a block of resistive switching dielectric material;
selectively removing portions of the first layer of conductive material to form a second block of conductive material, wherein the first block of conductive material is disposed directly on the block of resistive switching dielectric material, and the block of resistive switching dielectric material is disposed directly on the second block of conductive material, and wherein the first block of conductive material and the block of resistive switching dielectric material are displaced laterally from the first conductive contact;
forming an insulation layer over the first block of conductive material, the block of resistive switching dielectric material and the second block of conductive material; and
performing a third anneal process on the insulation layer.

11. The method of claim 10, wherein the insulation layer is silicon nitride.

12. The method of claim 10, comprising:
performing a second anneal process on the second layer of conductive material before the selectively removing portions of the second layer of conductive material.

13. The method of claim 10, comprising:
forming a second insulation material over the insulation layer;
forming a second contact hole extending through the second insulation material and the insulation layer; and
forming a second conductive contact in the second contact hole;
wherein the second conductive contact is in electrical contact with the first block of conductive material.

14. The method of claim 10, comprising:
forming a first region and a second region of a first conductivity type in the semiconductor substrate, wherein the semiconductor substrate is of a second conductivity type different than the first conductivity type;
forming a conductive gate disposed over and insulated from the semiconductor substrate, and between the first and second regions; and
electrically coupling the first conductive contact to the second region.

15. The method of claim 10, wherein the resistive switching dielectric material includes one of HfO2, Al2O3, TaOx, TiOx, WOx, VOx or CuOx.

16. The method of claim 10, wherein the resistive switching dielectric material includes a sublayer of HfO₂ and a sublayer of Al₂O₃.

17. The method of claim 10, wherein the resistive switching dielectric material includes a sublayer of HfO₂, a sublayer of Hf, and a sublayer of TaOx.

18. The method of claim 10, wherein the resistive switching dielectric material includes a sublayer of HfO₂, a sublayer of Ti, and a sublayer of TiOx.

19. A memory device, comprising:
a first insulation material disposed over a semiconductor substrate;
a first conductive contact extending through the first insulation material;
a second block of conductive material disposed on the first insulation material and on, and in electrical contact with, the first conductive contact;
a block of resistive switching dielectric material disposed directly on the second block of conductive material;
a first block of conductive material disposed directly on the block of resistive switching dielectric material, wherein the block of resistive switching dielectric material and the first block of conductive material are displaced laterally from the first conductive contact; and
an insulation layer over the first block of conductive material, the block of resistive switching dielectric material and the second block of conductive material.

20. The memory device of claim 19, wherein the insulation layer is silicon nitride.

21. The memory device of claim 19, comprising:
a second insulation material disposed over the insulation layer; and
a second conductive contact extending through the second insulation material and the insulation layer, wherein the second conductive contact is in electrical contact with the first block of conductive material.

22. The memory device of claim 19, comprising:
a first region and a second region of a first conductivity type in the semiconductor substrate, wherein the semiconductor substrate is of a second conductivity type different than the first conductivity type; and
a conductive gate disposed over and insulated from the semiconductor substrate, and between the first and second regions;
wherein the first conductive contact is electrically coupled to the second region.

23. The memory device of claim 19, wherein the block of resistive switching dielectric material includes one of HfO₂, Al₂O₃, TaOx, TiOx, WOx, VOx or CuOx.

24. The memory device of claim 19, wherein the block of resistive switching dielectric material includes a sublayer of HfO₂ and a sublayer of Al₂O₃.

25. The memory device of claim 19, wherein the block of resistive switching dielectric material includes a sublayer of HfO₂, a sublayer of Hf, and a sublayer of TaOx.

26. The memory device of claim 19, wherein the block of resistive switching dielectric material includes a sublayer of HfO₂, a sublayer of Ti, and a sublayer of TiOx.
